(19) United States
(12) Patent Application Publication
(10) Pub. No.: US 2024/0038868 A1
(43) Pub. Date: Feb. 1, 2024

(54) SEMICONDUCTOR DEVICE

(71) Applicant: DENSO CORPORATION, Kariya-city (JP)

(72) Inventor: RYOTA MIWA, Kariya-city (JP)

(21) Appl. No.: 18/318,076

(22) Filed: May 16, 2023

(30) Foreign Application Priority Data
Jul. 26, 2022 (JP) 2022-119053

(51) Int. Cl. H01L 29/43; H01L 29/739

(52) U.S. Cl. CPC H01L 29/435; H01L 29/7393

(57) ABSTRACT

A semiconductor element includes an element having a gate electrode provided in a semiconductor substrate. The semiconductor substrate has an emitter electrode arranged on an upper surface and a collector electrode arranged on a lower surface. A gate pad is arranged at a different position from the emitter electrode on the upper surface. A gate resistor arranged on the upper surface has an adjustable resistance value, and is connected between the gate electrode and the gate pad.

### CROSS REFERENCE TO RELATED APPLICATION

The application is based on a Japanese Patent Application No. 2022-119053 filed on Jul. 26, 2022, the contents of which are incorporated herein by reference in its entirety.

### TECHNICAL FIELD

The present disclosure relates to a semiconductor device.

### BACKGROUND

In a semiconductor device, a resistance value of a variable resistor is changeable by a control unit.

### SUMMARY

According to an aspect of the present disclosure, a semiconductor device includes a semiconductor substrate in which an element having a gate electrode is provided, a first main electrode arranged on a first surface of the semiconductor substrate, a second main electrode arranged on a second surface opposite to the first surface in a substrate thickness direction, a gate pad arranged on the first surface of the semiconductor substrate at a position different from a position of the first main electrode, and a gate resistor having an adjustable resistance value. In the semiconductor device, the gate resistor may be arranged on the first surface of the semiconductor substrate, and may be connected to a position between the gate electrode and the gate pad.

### BRIEF DESCRIPTION OF THE DRAWINGS

Objects, features, and advantages of the present disclosure will become more apparent from the following detailed description made with reference to the accompanying drawings, in which:

FIG. 1 is a schematic diagram showing a configuration of a vehicle drive system to which a semiconductor device according to a first embodiment of the present disclosure is applied;

FIG. 2 is a plan view of a semiconductor device according to the first embodiment;

FIG. 3 is a cross-sectional view taken along a line III-III in FIG. 2;

FIG. 4 is a cross-sectional view taken along a line IV-IV in FIG. 2;

FIG. 5 is a plan view showing a semiconductor element;

FIG. 6 is a diagram showing an equivalent circuit of the semiconductor device;

FIG. 7 is a cross-sectional view taken along a line VII-VII in FIG. 5;

FIG. 8 is a diagram showing a pattern of gate resistors and arrangement of adjuster pads;

FIG. 9 is a diagram showing a procedure of a resistance value adjustment;

FIG. 10 is a diagram showing a method of adjusting a gate resistance;

FIG. 11 is a diagram showing a relationship between a carrier frequency, a switching speed, a surge voltage, and a switching loss;

FIG. 12 is a diagram showing an arrangement of gate resistor patterns and adjuster pads in a semiconductor device according to a second embodiment of the present disclosure;

FIG. 13 is a diagram showing a method of adjusting a gate resistance;

FIG. 14 is a diagram showing a pattern of gate resistor in a semiconductor device according to a third embodiment of the present disclosure;

FIG. 15 is a cross-sectional view taken along a line XV-XV in FIG. 14;

FIGS. 16A to 16C are diagrams respectively showing an example of laser cutting;

FIG. 17 is a diagram showing a laser cutting according to a modification of the present disclosure; and

FIG. 18 is a diagram showing a laser cutting according to another modification of the present disclosure.

### DESCRIPTION OF EMBODIMENTS

In a semiconductor device, a resistance value of a variable resistor may be changeable by a control unit. When a carrier frequency of Pule Width Modulation (PWM) is raised to a high frequency, passive components and a power conversion device may be made smaller and may have a lighter weight. Furthermore, the ripple current of a motor may be reduced at the same time. However, switching loss increases in proportion to the carrier frequency. For reducing the switching loss, the switching speed should be raised to high speed, but the surge voltage increases as the switching speed rises. Therefore, the switching element must be operated at a speed at which the surge voltage does not exceed a withstand voltage of the switching element.

For example, a surge voltage may be measured, and a resistance value of a variable resistor may be changed based on the surge voltage measurement result. However, for implementing the above, a variable resistor is required to be provided outside the switching element and a surge voltage measurement circuit is also required to be used, thereby complicating the configuration. From the viewpoint described above and/or from other viewpoints not mentioned, further improvement is required for the semiconductor device.

It is an object of the present disclosure to provide a semiconductor device capable of reducing switching loss with a simple configuration.

According to an exemplar of the present disclosure, a semiconductor device includes a semiconductor substrate in which an element having a gate electrode is provided, a first main electrode arranged on a first surface of the semiconductor substrate, a second main electrode arranged on a second surface opposite to the first surface in a substrate thickness direction, a gate pad arranged on the first surface of the semiconductor substrate at a position different from a position of the first main electrode, and a gate resistor having an adjustable resistance value. In the semiconductor device, the gate resistor is arranged on the first surface of the semiconductor substrate and is connected to a position between the gate electrode and the gate pad.

According to the semiconductor device of the present disclosure, the gate resistor in which the resistance value is adjustable is provided on the first surface of the semiconductor substrate. In other words, the semiconductor device is provided with a built-in gate resistor in which the resistance value is adjustable. Therefore, the resistance value of the gate resistor can be adjusted in accordance with element characteristics. As a result, it is possible to provide a semiconductor device capable of reducing switching loss with a simple configuration.

For example, the gate resistor may be made of silicon, and may be configured to have a ladder structure. The gate resistor may include a plurality of connecting parts provided in parallel between the gate electrode and the gate pad, and a plurality of adjuster pads provided respectively in the plurality of connecting parts to adjust the resistance value. Furthermore, each of the connecting parts may include a reduced-width portion, a first widened portion that is connected to one end of the reduced-width portion and is wider than the reduced-width portion, and a second widened portion that is connected to an another end of the first widened portion and is wider than the reduced-width portion. In this case, the adjuster pad may be provided in the first widened portion and the second widened portion in each of the connecting parts.

Alternatively, each of the connecting parts may include a reduced-width portion, and a widened portion that is connected to one end of the reduced-width portion and is wider than the reduced-width portion. In this case, the adjuster pad may be provided in the reduced-width portion in each of the connecting parts.

Hereinafter, multiple embodiments are described with reference to the drawings. The same reference numerals are assigned to the corresponding elements in each of the embodiments, and thus, duplicate descriptions may be omitted. In each of the embodiments, when only a part of the configuration is described, the rest of the configuration may adopt corresponding parts of other preceding embodiment(s). Further, it is possible to not only combine configurations as explicitly specified in the description of the respective embodiments, but also combine configurations of the respective embodiments at least partially even though not explicitly specified herein as long as the combination is not hindered.

A semiconductor device of the present embodiment may be applied, for example, to a power conversion device for a moving object that uses a rotating electric machine as a driving power source. Examples of the moving object may include electric land vehicles such as battery electric vehicles (BEV), hybrid vehicles (HEV), and plug-in hybrid vehicles (PHEV), flying vehicles such as electric vertical takeoff and landing aircraft or drones, ships, construction machinery, and agricultural machinery. An example applied to a vehicle is described in the following.

### First Embodiment

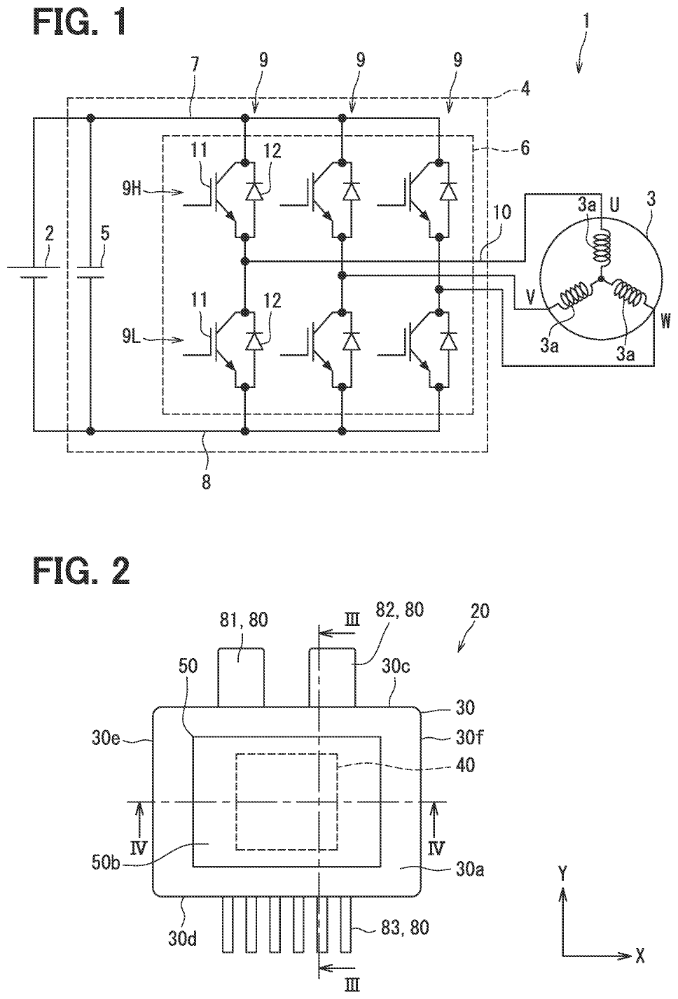

First of all, a configuration of a vehicle drive system according to a first embodiment will be described with reference to FIG. 1.

### Vehicle Drive System

As shown in FIG. 1, a vehicle drive system 1 is provided with a direct current (DC) power supply 2, a motor generator 3, and a power conversion device 4.

The DC power supply 2 is a direct-current voltage source including a chargeable/dischargeable secondary battery. The secondary battery is, for example, a lithium-ion battery or a nickel-hydride battery. The motor generator 3 is a three-phase alternating-current (AC) type rotating electric machine. The motor generator 3 functions as a vehicle driving power source, that is, an electric motor. The motor generator 3 functions also as a generator during regeneration. The power conversion device 4 performs electric power conversion between the DC power supply 2 and the motor generator 3.

### Power Conversion Device

Next, based on FIG. 1, the circuit configuration of the power conversion device 4 is described. The power conversion device 4 includes a power conversion circuit. As shown in FIG. 1, the power conversion device 4 includes a smoothing capacitor 5 and an inverter 6 that is a power conversion circuit.

The smoothing capacitor 5 mainly smooths the DC voltage supplied from the DC power supply 2. The smoothing capacitor 5 is connected to a P line 7 that is a power line on a high-potential side and an N line 8 that is a power line on a low-potential side. The P line 7 is connected to a positive electrode of the DC power supply 2, and the N line 8 is connected to a negative electrode of the DC power supply 2. The positive electrode of the smoothing capacitor 5 is connected to the P line 7 at a position between the DC power supply 2 and the inverter 6. Similarly, the negative electrode of the smoothing capacitor 5 is connected to the N line 8 at a position between the DC power supply 2 and the inverter 6. The smoothing capacitor 5 is connected in parallel with the DC power supply 2.

The inverter 6 corresponds to a DC-AC conversion circuit. The inverter 6 converts the DC voltage into a three-phase AC voltage, and outputs the three-phase AC voltage to the motor generator 3 according to switching control by a control circuit (not shown). Thereby, the motor generator 3 is driven to generate a predetermined torque. During regenerative braking of the vehicle, the inverter 6 converts the three-phase AC voltage generated by the motor generator 3 in response to the torque from the wheels into the DC voltage according to switching control by the control circuit, and outputs the DC voltage to the P line 7. In such manner, the inverter 6 performs bi-directional power conversion between the DC power supply 2 and the motor generator 3.

The inverter 6 includes upper and lower arm circuits 9 for three phases. The upper and lower arm circuits 9 may also be referred to as legs. The upper and lower arm circuits 9 respectively have an upper arm 9H and a lower arm 9L. The upper arm 9H and the lower arm 9L are connected in series between the P line 7 and the N line 8 while the upper arm 9H is positioned on a side of the P line 7. A connection point between the upper arm 9H and the lower arm 9L is connected to a corresponding phase winding 3a in the motor generator 3 via an output line 10. The inverter 6 has six arms, for example. At least a part of each of the P line 7, the N line 8 and the output line 10 is made of a conductive member such as a bus bar or the like.

Elements forming each arm include an insulated gate bipolar transistor 11 (hereinafter referred to as an IGBT 11) as a switching element and a reflux diode 12. In the present embodiment, an n-channel type IGBT 11 is adopted. The reflux diode 12 is connected in anti-parallel with corresponding IGBT 11. A collector of the IGBT 11 is connected to the P line 7 in the upper arm 9H. An emitter of the IGBT 11 is connected to the N line 8 in the lower arm 9L. The emitter of the IGBT 11 on the upper arm 9H and the collector of the IGBT 11 on the lower arm 9L are connected to each other. An anode of the reflux diode 12 is connected to the emitter of the corresponding IGBT 11, and a cathode of the reflux diode 12 is connected to the collector of the corresponding IGBT 11.

The power conversion device 4 may further include a converter as a power conversion circuit. The converter is a DC-DC converter circuit for converting the DC voltage to a DC voltage with different value. The converter is disposed at a position between the DC power supply 2 and the smoothing capacitor 5. The converter is configured to include, for example, a reactor and the above-described upper and lower arm circuits 9. According to such a configuration, it is possible to step up or down the voltage. The power conversion device 4 may further include a filter capacitor for removing power supply noise from the DC power supply 2. The filter capacitor is provided at a position between the DC power supply 2 and the converter.

The power conversion device 4 may include a drive circuit for switching elements forming the inverter 6 and the like. The drive circuit supplies a drive voltage to a gate of the IGBT 11 of the corresponding arm based on a drive instruction of the control circuit. The drive circuit drives the corresponding IGBT 11 by applying a drive voltage to turn on and off the drive of the corresponding IGBT 11. The drive circuit may also be referred to as a driver.

The power conversion device 4 may include a control circuit for switching elements. The control circuit generates a drive instruction for operating the IGBT 11, and outputs it to the drive circuit. The control circuit generates the drive instruction based on a torque request input from a higher-level ECU (not shown) or signals detected by various sensors. Various sensors include, for example, a current sensor, a rotation angle sensor, and a voltage sensor. The current sensor detects a phase current flowing through the phase winding 3a of each phase. The rotation angle sensor detects a rotation angle of a rotor of the motor generator 3. The voltage sensor detects a voltage across two ends of the smoothing capacitor 5. The control circuit outputs, for example, a PWM signal as the drive instruction. The control circuit includes, for example, a processor and a memory. ECU is an abbreviation of Electronic Control Unit. PWM is an abbreviation of Pulse Width Modulation.

### Semiconductor Device

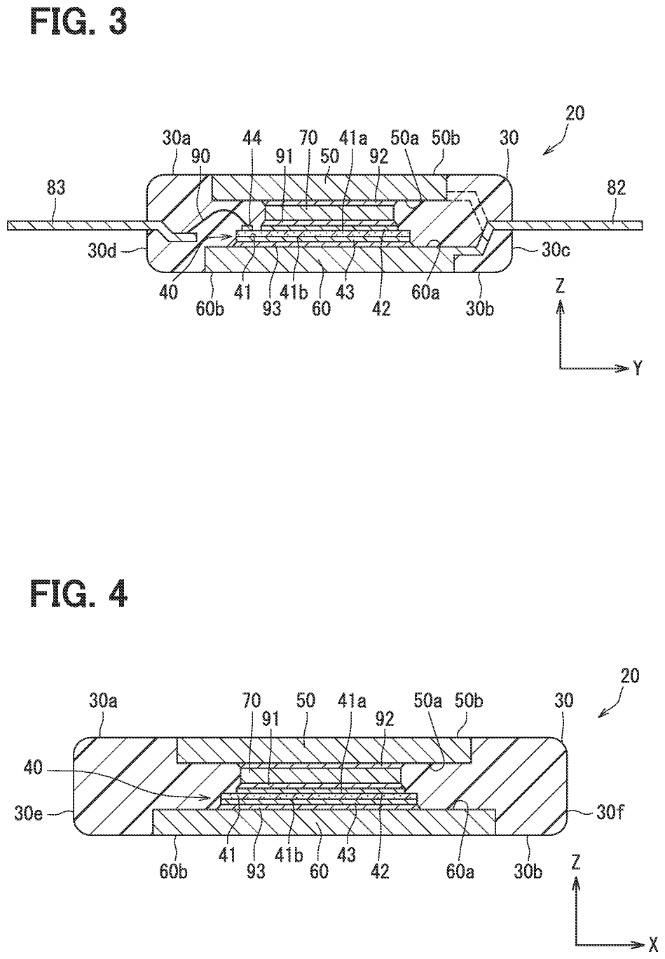

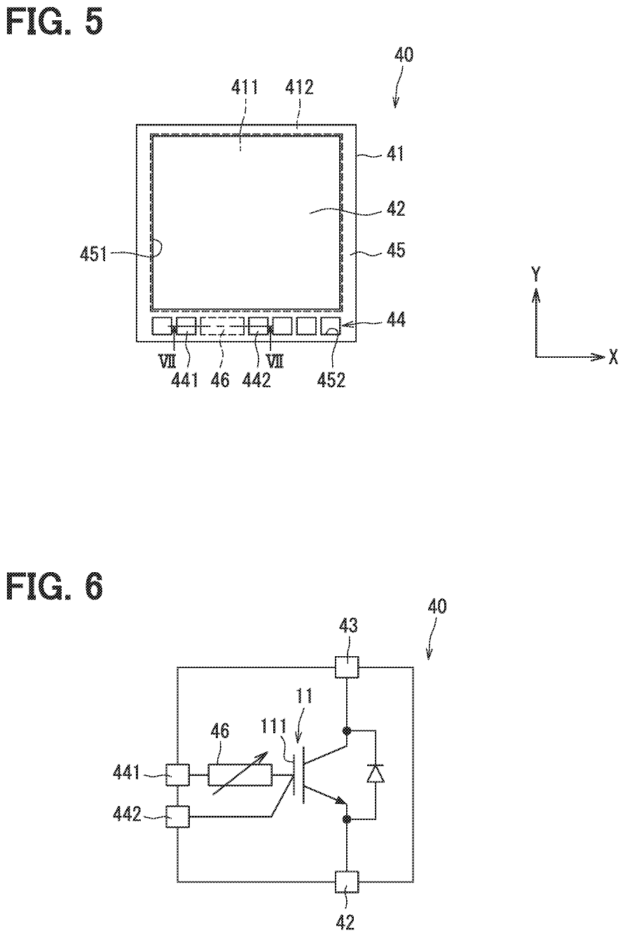

Next, a schematic configuration of a semiconductor device including a semiconductor element will be described with reference to FIGS. 2 to 5. FIG. 2 is a plan view showing the semiconductor device according to the present embodiment. FIG. 2 is a plan view of the semiconductor device when being viewed from a top of the device. FIG. 3 is a cross-sectional view taken along a line III-III in FIG. 2. FIG. 4 is a cross-sectional view taken along a line IV-IV in FIG. 2. For convenience, a protective film is omitted to be indicated in FIGS. 3 and 4. FIG. 5 is a plan view showing the semiconductor element.

In the Figures, the substrate thickness direction of the semiconductor element (i.e., a semiconductor substrate) is defined as the Z direction. One direction perpendicular to the Z direction is defined as the X direction. A direction perpendicular to both of the Z direction and the X direction is defined as the Y direction. Unless otherwise specified, a shape viewed in a plane from the Z-direction, that is, a shape along an XY plane defined by the X-direction and Y-direction is referred to as a planar shape. Also, “a plan view from the Z direction” may simply be referred to as a plan view.

As shown in FIGS. 2 to 4, a semiconductor device 20 includes a sealing body 30, a semiconductor element 40, wiring members 50 and 60, a conductive spacer and an external connection terminal 80. The semiconductor device 20 further includes bonding wires 90 and bonding materials 91, 92 and 93. The semiconductor device 20 constitutes one of the arms described above. That is, two semiconductor devices 20 constitute the upper and lower arm circuits 9 for one phase.

The sealing body 30 seals a part of other elements that constitute the semiconductor device 20. The rest part of the other elements is exposed outside the sealing body 30. The sealing body 30 is made of resin, for example. An example of the resin is an epoxy resin. The sealing body 30 is made of resin and is molded by, for example, a transfer molding method. Such a sealing body 30 may sometimes be referred to as a sealing resin body, mold resin, resin molded body, or the like. The sealing body 30 may be formed using gel, for example. The gel fills an opposing region of the pair of wiring members 50 and 60, for example. In this case, the gel is positioned at an opposing region of the pair of wiring members 50 and 60.

As shown in FIGS. 2 to 4, the sealing body 30 has a substantially rectangular planar shape. The sealing body 30 has an upper surface 30a and a lower surface 30b opposite to the upper surface 30a in the Z direction as surfaces forming an outline. The upper surface 30a and the lower surface 30b are, for example, substantially flat surfaces. It also has side surfaces 30c, 30d, 30e, and 30f that are continuous with the upper surface 30a and the lower surface 30b. The side surface is a surface from which main terminals 81 and 82 of the external connection terminal 80 protrude. The side surface 30d is a surface opposite to the side surface in the Y direction. The side surface 30d is a surface from which a signal terminal 83 protrudes. The side surfaces 30e and 30f are surfaces from which the external connection terminal 80 do not protrude. The side surface 30e is a surface opposite to the side surface 30f in the X direction.

The semiconductor element 40 includes a semiconductor substrate 41, an emitter electrode 42, a collector electrode 43, a pad 44, a protective film 45, and the like. The semiconductor element 40 is sometimes referred to as a semiconductor chip. The semiconductor substrate 41 is made of silicon (Si), a wide bandgap semiconductor having a wider bandgap than silicon, or the like, and is configured to have a vertical element formed thereon. Examples of the wide bandgap semiconductor include silicon carbide (SiC), gallium nitride (GaN), gallium oxide (Ga2O3), and diamond.

The vertical element is configured to allow a main current to flow in the thickness direction of the semiconductor substrate 41 (i.e., a semiconductor element that is, in the Z direction. The vertical element of the present embodiment may be the IGBT 11 and the reflux diode 12 that form one arm. The vertical element may be an IGBT in which the reflux diode 12 is connected in anti-parallel, that is, an RC (Reverse Conducting)-IGBT. A vertical element is a heating element that generates heat when energized. A gate electrode (not shown) is formed on the semiconductor substrate 41. The gate electrode has, for example, a trench structure.

As shown in FIG. 5, the semiconductor substrate 41 has a substantially rectangular planar shape. The semiconductor substrate 41 has an active region 411 and a peripheral region 412. The active region 411 is a formation region for vertical devices. The active region 411 may be called as a main region, a main cell region, a cell region, an element region, an element formation region, or the like. A pressure resistance structure (not shown) such as a guard ring is formed in the peripheral region 412.

The semiconductor substrate 41 has an upper surface 41a and a lower surface 41b as substrate surfaces on which the main electrodes are provided. The upper surface 41a is a surface of the semiconductor substrate 41 on a side of an upper surface 30a of the sealing body 30. The lower surface 41b is a surface opposite to the upper surface 41a in the substrate thickness direction. The emitter electrode 42, which is one of the main electrodes, is arranged on the upper surface 41a of the semiconductor substrate 41. The collector electrode 43, which is another one of the main electrodes, is arranged on the lower surface 41b of the semiconductor substrate 41. The emitter electrode 42 corresponds to a first main electrode, and the collector electrode 43 corresponds to a second main electrode, for example.

When the IGBT 11 is turned on, an electric current (i.e., a main current) flows between the main electrodes, that is, between the emitter electrode 42 and the collector electrode 43. The emitter electrode 42 also serves as an anode electrode of the reflux diode 12. The collector electrode 43 also serves as a cathode electrode of the reflux diode 12. The collector electrode 43 is formed to cover an almost entire lower surface 41b of the semiconductor substrate 41. The emitter electrode 42 is formed on a portion of the upper surface 41a of the semiconductor substrate 41. The emitter electrode 42 is provided to include the active region 411 in a plan view, for example.

The pads 44 are electrodes for signals. The pad 44 is formed in a region different from the formation region of the emitter electrode 42 on the upper surface 41a of the semiconductor substrate 41. The pad 44 is provided at a position overlapping the peripheral region 412 in a plan view. The pad 44 is formed at an end portion opposite to the formation region of the emitter electrode 42 in the Y direction. The pad 44 is provided side by side with the emitter electrode 42 in the Y direction. The number of pads 44 is not particularly limited. The pads 44 include at least pads for gate electrodes.

As an example, as shown in FIG. 5, the semiconductor element 40 has six pads 44. Specifically, the pad 44 is used for a gate electrode, an emitter potential detection, a cathode potential detection of a temperature-sensitive diode (not shown) provided in the semiconductor element 40, an anode potential detection, a current sensing, and an OFF-holding. The pad for OFF-holding is a pad to which a signal for forcibly keeping the switching element (i.e., IGBT 11) formed on the semiconductor substrate 41 in an OFF state is inputted.

The protective film 45 is arranged on the upper surface 41a of the semiconductor substrate 41. The protective film 45 is an insulating film provided on the upper surface 41a of the semiconductor substrate 41 to cover a periphery of the emitter electrode 42. As a material for the protective film 45, for example, polyimide, a silicon nitride film, or the like can be used.

As shown in FIG. 5, the protective film 45 has an opening 451 that defines a bonding region between the emitter electrode 42 and the bonding material 91. The opening 451 is a through hole penetrating the protective film 45 in the Z direction. The opening 451 is provided to overlap the emitter electrode 42 in a plan view. Similarly, the protective film 45 has openings 452 that define the bonding regions of the pads 44. The details of the structure of the semiconductor element 40 are described later.

The wiring member 50 is electrically connected to the emitter electrode 42, and provides a wiring function. Similarly, the wiring member 60 is electrically connected to the collector electrode 43, and provides a wiring function. The wiring members 50 and 60 are arranged to sandwich the semiconductor element 40 in the Z direction. The wiring members 50 and 60 are arranged so that at least parts of them face each other in the Z direction. The wiring members 50 and 60 include the semiconductor element 40 in a plan view.

The wiring members 50 and 60 provide a heat dissipation function for dissipating heat generated by the semiconductor element 40. The wiring members 50 and 60 may be used as a radiator plate, a heat sink, or the like. The wiring members 50 and 60 of the present embodiment are metal plates made of metal with good conductivity such as Cu, Cu alloys and the like. The metal plate is provided, for example, as part of a lead frame. Instead of the metal plate, a substrate in which metal bodies are arranged on both surfaces of an insulating base material may be employed. The wiring members 50 and 60 may have a plated film of Ni, Au, or the like on the surfaces.

The wiring member 50 has a facing surface 50a, which is a surface facing the semiconductor element 40, and a reverse surface 50b, which is a surface opposite to the facing surface 50a. Similarly, the wiring member 60 also has a facing surface 60a and a reverse surface 60b. The wiring members 50 and 60 are, for example, substantially rectangular in a plan view. The reverse surfaces 50b and 60b of the wiring members 50 and 60 are exposed from the sealing body 30. The reverse surfaces 50b and 60b are sometimes referred to as heat dissipation surfaces, exposed surfaces, and the like. The reverse surface 50b of the wiring member 50 is substantially flush with the upper surface 30a of the sealing body 30. That is, the reverse surface 50b of the wiring member 50 and the upper surface 30a of the sealing body 30 are substantially on the same surface. The reverse surface 60b of the wiring member 60 is substantially flush with the lower surface 30b of the sealing body 30. That is, the reverse surface 60b of the wiring member 60 and the lower surface 30b of the sealing body 30 are substantially on the same surface.

The conductive spacer 70 is interposed between the semiconductor element 40 and the wiring member 50. The conductive spacer 70 provides a spacer function of reserving a predetermined distance between the semiconductor element 40 and the wiring member 50. For example, the conductive spacer 70 provides a height for electrically connecting the signal terminals 83 to the corresponding pads 44 of the semiconductor element 40. The conductive spacer 70 is positioned in a middle of the electrical and thermal conduction path between the emitter electrode 42 of the semiconductor element 40 and the wiring member 50, and provides a wiring function and a heat dissipation function.

The conductive spacer 70 contains a metal material such as Cu that has good electrical and thermal conductivity. The conductive spacer 70 may have a plated film on its surface. The conductive spacer 70 may sometimes be referred to as terminals, terminal blocks, metal blocks, and the like. The conductive spacer 70 of the present embodiment is a columnar body having a substantially rectangular planar shape.

The external connection terminal 80 is a terminal for electrically connecting the semiconductor device 20 to an external device. The external connection terminal 80 is formed using a metal material with good conductivity such as copper. The external connection terminal 80 is, for example, a plate material. The external connection terminal 80 may sometimes be called as a lead. The external connection terminal 80 includes the main terminals 81 and 82 and the signal terminal 83. The main terminals 81 and 82 are respectively an external connection terminal 80 electrically connected to the main electrodes of the semiconductor element 40.

The main terminal 81 is electrically connected to the emitter electrode 42. The main terminal 81 is an emitter terminal for the emitter electrode 42. The main terminal 81 is connected to the emitter electrode 42 via the wiring member 50. The main terminal 81 is connected to one end of the wiring member 50 in the Y direction. The thickness of the main terminal 81 is thinner than that of the wiring member 50. The main terminal 81 is connected to the wiring member 50 so that a surface thereof is flush with the facing surface 50a, for example. The main terminal 81 may be provided to have an integrated body (i.e., one body) with the wiring member 50 to be connected with the wiring member 50, or may be provided as a separate member and connected to the wiring member 50 by joining.

The main terminal 81 of the present embodiment is provided integrally with the wiring member 50 as part of a lead frame. The main terminal 81 extends in the Y direction from the wiring member 50 and protrudes outside from the side surface 30c of the sealing body 30. The main terminal 81 has a bent portion in the middle of a part covered with the sealing body 30, and protrudes from a vicinity of a center in the Z direction on the side surface 30c.

The main terminal 82 is electrically connected to the collector electrode 43. The main terminal 82 is used as a collector terminal of the collector electrode 43. The main terminal 82 is connected to the collector electrode 43 via the wiring member 60. The main terminal 82 is connected to one end of the wiring member 60 in the Y direction. The thickness of the main terminal 82 is thinner than that of the wiring member 60. The main terminal 82 is connected to the wiring member 60 so that a surface thereof is flush with the facing surface 60a, for example. The main terminal 82 may be provided to have an integrated body with the wiring member 60, or may be provided as a separate member and connected thereto by joining.

The main terminal 82 of the present embodiment is provided integrally with the wiring member 60 as a part of a lead frame different from the main terminal 81. The main terminal 82 extends in the Y direction from the wiring member 60 and protrudes outside from the side surface 30c on the same side as the main terminal 81. The main terminal 82 also has a bent portion in a middle part covered with the sealing body 30, and protrudes from a vicinity of a center in the Z direction on the side surface 30c. The two main terminals 81, 82 are arranged side by side in the X direction so that side surfaces of the two main terminals 81, 82 face each other.

The signal terminals 83 are electrically connected to corresponding pads 44 of the semiconductor element 40. The signal terminal 83 is electrically connected to the pad 44 via the bonding wire 90. The signal terminal 83 extends in the Y direction and protrudes outside from the side surface 30d of the sealing body 30. The semiconductor device 20 of the present embodiment has six signal terminals 83 corresponding to the pads 44. The six signal terminals 83 are arranged side by side in the X direction. The signal terminal 83 is formed on a lead frame that is used in common to the wiring member 60 and the main terminal 82, for example. The plurality of signal terminals 83 are electrically isolated from each other by cutting tie bars (not shown).

The bonding material 91 is interposed between the emitter electrode 42 of the semiconductor element 40 and the conductive spacer 70 to bond the emitter electrode 42 and the conductive spacer 70 together. The bonding material 92 is interposed between the conductive spacer 70 and the wiring member 50 to bond the conductive spacer 70 and the wiring member 50 together. The bonding material 93 is interposed between the collector electrode 43 of the semiconductor element 40 and the wiring member 60 to bond the collector electrode 43 and the wiring member 60 together.

The bonding materials 91, 92, and 93 may be made of the same material or may be made of different materials. As an example, the bonding materials 91, 92, 93 are solder. For example, multi-component lead-free solder containing Sb, Bi or the like, in addition to Sn can be employed.

As described above, the semiconductor device 20 includes the semiconductor element 40 defining one arm. The semiconductor element 40 is sealed with the sealing body 30. The sealing body 30 integrally seals the semiconductor element 40, a part of the wiring member 50, a part of the wiring member 60, and a part of each of the conductive spacer 70 and the external connection terminal 80.

The semiconductor element 40 is arranged at a position between the wiring members 50 and 60 in the Z direction. The semiconductor element 40 is sandwiched between the wiring members 50 and 60 arranged to face each other. Thereby, the heat of the semiconductor element 40 can be dissipated to both sides in the Z direction via the wiring members 50 and 60. The semiconductor device 20 has a double-sided heat dissipation structure. The reverse surface 50b of the wiring member 50 is substantially on the same surface as the upper surface 30a of the sealing body 30. The reverse surface 60b of the wiring member 60 is substantially on the same surface as the lower surface 30b of the sealing body 30. Since the reverse surfaces 50b and 60b are exposed surfaces, heat dissipation can be facilitated.

### Semiconductor Element

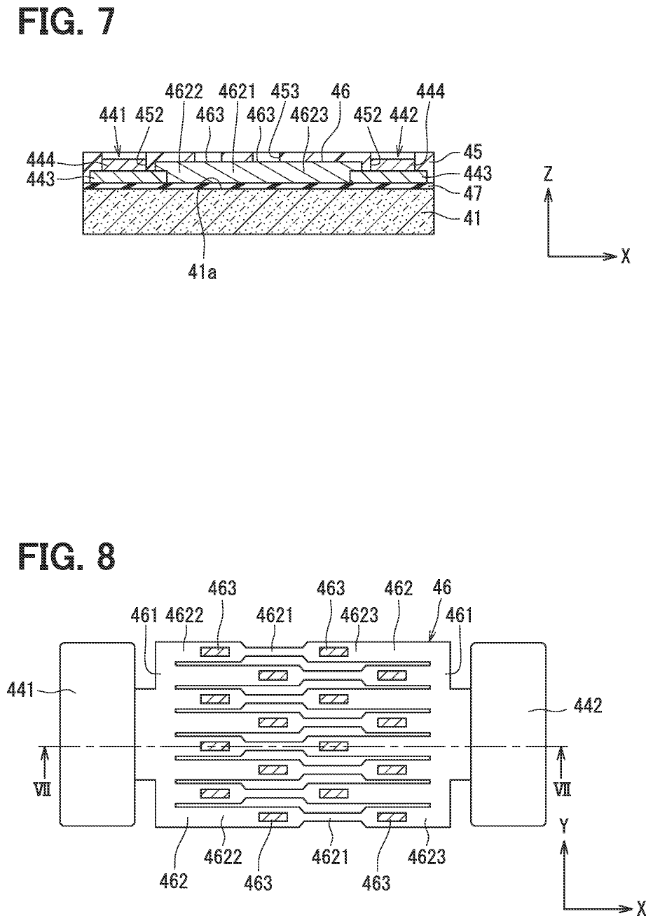

Next, based on FIGS. 5 to 8, the structure of the semiconductor element, especially a gate resistor, is described. In FIG. 5, adjuster pads are omitted for the sake of convenience. FIG. 6 is an equivalent circuit diagram of a semiconductor element. In FIG. 6, sense elements and current sensing pads are omitted for convenience. FIG. 7 is a cross-sectional view taken along a line VII-VII in FIG. 5. FIG. 8 is a diagram showing a pattern of gate resistors and arrangement of adjuster pads. A line VII-VII shown in FIG. 8 corresponds to a line VII-VII shown in FIG. 5.

As shown in FIGS. 5 to 8, the semiconductor device 40 further includes a gate resistor 46. The semiconductor element 40 has the built-in gate resistor 46. As shown in FIG. 6, the gate resistor 46 is connected to a position between a gate electrode 111 and a gate pad 441 of the IGBT 11. The gate resistor 46 electrically connects the gate electrode 111 and the gate pad 441 via a gate wiring (not shown). As an example, the semiconductor element 40 of the present embodiment has an OFF-holding pad 442. The gate resistor 46 is connected to a position between the gate pad 441 and the OFF-holding pad 442.

As shown in FIG. 7, the gate pad 441 and the OFF-holding pad 442 are arranged on the upper surface 41a of the semiconductor substrate 41. The gate pad 441 and the OFF-holding pad 442 are arranged on the upper surface 41a with an insulating film 47 such as a silicon oxide film interposed therebetween. The gate pad 441 has a structure similar to that of the emitter electrode 42, specifically a multi-layer structure. The gate pad 441 has a base layer 443 and a connection layer 444. The pads 44 other than the gate pad 441 have the same configuration as the gate pad 441.

The base layer 443 of the gate pad 441 is arranged on the insulating film 47. The base layer 443 is formed using a material whose main component is Al (aluminum), for example. As an example, in the present embodiment, Al alloys such as AlSi or AlSiCu may be used as the material of the base layer 443. A peripheral portion of the base layer 443 is covered with a protective film 45.

The connection layer 444 is stacked on the base layer 443 for the purpose of improving bonding strength and bonding properties. The connection layer 444 is sometimes referred to as an overlay layer. The connection layer 444 includes at least one metal layer. The metal layer serving as the connection layer 444 includes, for example, any one of Ni, Pd, Au, Pt, and Ag.

The connection layer 444 of the present embodiment includes at least a Ni (nickel) layer. Ni is harder than the Al alloy forming the base layer 443. An Au (gold) layer may be further provided on the Ni layer. The connection layer 444 is stacked on the base layer 443 and exposed through the opening 452. As an example, the connection layer 444 of the present embodiment is arranged on the base layer 443 in the opening 452. The outer peripheral edge of the connection layer 444 is in contact with a wall surface of the protective film 45 that defines the opening 452.

The gate resistor 46 contains silicon as a material. The gate resistor 46 is, for example, a polysilicon resistor in which impurities are implanted into polysilicon. As shown in FIG. 8, the gate resistor 46 has a ladder structure. The gate resistor 46 has two pillars 461 and a plurality of connecting parts 462. Each of the plurality of connecting parts 462 bridges the two pillars 461. One of the ends of the connecting part 462 is connected to one of the pillars 461, and the other one of the ends of the connecting part 462 is connected to the other one of the pillars 461.

The gate resistor 46 extends over the peripheral edge of the base layer 443 of the gate pad 441, the insulating film 47, and the peripheral edge of the base layer 443 of the OFF-holding pad 442. The gate resistor 46 is arranged on the peripheral portion of the base layer 443 and on the insulating film 47. The gate resistor 46 is connected to the gate pad 441 and to the OFF-holding pad 442. The two pillars 461 are provided in series between the gate pad 441 and the OFF-holding pad 442.

A plurality of connecting parts 462 are provided in parallel with each other between the gate pad 441 and the OFF-holding pad 442. The plurality of connecting parts 462 are provided in parallel between the gate electrode and the gate pad 441. As an example, in the present embodiment, the gate resistor 46 has eight connecting parts 462. The pillar 461 extends in the Y direction. The connecting part 462 extends in the X direction. The plurality of connecting parts 462 are arranged side by side in the Y direction.

Each of the connecting parts 462 has a reduced-width portion 4621 and widened portions 4622 and 4623. In the following, the width means a length of the connecting part 462 in a direction orthogonal to the longitudinal direction (i.e., extending direction). The widened portions 4622 and 4623 are wider than the reduced-width portion 4621. In the longitudinal direction, one end of the reduced-width portion 4621 is connected to the widened portion 4622, and the other end of the reduced-width portion 4621 is connected to the widened portion 4623. The connecting part 462 has the widened portions 4622 and 4623 at both ends in the longitudinal direction, and has the reduced-width portion 4621 between the widened portions 4622 and 4623. The reduced-width portion 4621 may sometimes be referred to as a narrow width portion. The widened portion 4622 and 4623 may sometimes be referred to as a wide width portion.

The widths of the widened portions 4622 and 4623 may be substantially equal to each other or may be different from each other. As an example, in the present embodiment, the widened portions 4622 and 4623 have substantially the same width. The widened portion 4622 corresponds to a first widened portion, and the widened portion 4623 corresponds to a second widened portion.

The gate resistor 46 has a plurality of adjuster pads 463 for adjusting a resistance value. The adjuster pad 463 is provided on each of the connecting parts 462. The adjuster pad 463 is a needle contact pad that cuts the reduced-width portion 4621 by energization. As an example, the adjuster pad 463 of the present embodiment is provided on each of the widened portions 4622 and 4623. That is, two adjuster pads 463 are provided for one connecting part 462.

The adjuster pad 463 is exposed through the opening 453 of the protective film 45. The adjuster pad 463 may be a part of a polysilicon resistor exposed from the opening 453, or may be a metal layer laminated on the polysilicon resistor.

### Resistance Adjustment Method

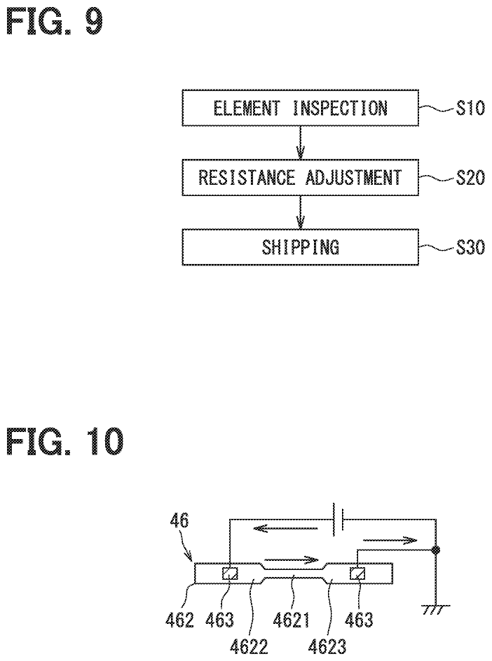

Next, a resistance adjustment method is described with reference to FIGS. 7 to 10. FIG. 9 is a diagram showing a procedure of resistance adjustment. FIG. 10 is a diagram showing a method of adjusting a gate resistance. Solid arrows shown in FIG. respectively indicate a current flow.

After forming the semiconductor element 40, an element inspection is performed at step S10, as shown in FIG. 9. In the element inspection at S10, element characteristics are inspected. Next, resistance adjustment is performed at step S20. In the resistance adjustment, the resistance value of the gate resistor 46 is adjusted as required based on the inspection result of the element characteristics.

Specifically, as shown in FIG. 10, needles are brought into contact with the two adjuster pads 463 provided on the connecting part 462 to be cut, and a voltage or an electric current is applied. Then, the reduced-width portion 4621 is cut (i.e., fused). For example, the cutting is performed by Joule heat or EM. A desired resistance value can be obtained by adjusting the number of connecting parts 462 to be cut. EM is an abbreviation of Electro Migration.

After adjusting the resistance, the product is shipped as shown at step S30 of FIG. 9. The semiconductor device 20 is shipped with the resistance value of the gate resistor 46 individually adjusted. FIG. 8 shows a state in which none of the connecting parts 462 are cut for the convenience. Depending on the product, the semiconductor device is shipped in a state in which some of the connecting parts 462 are cut.

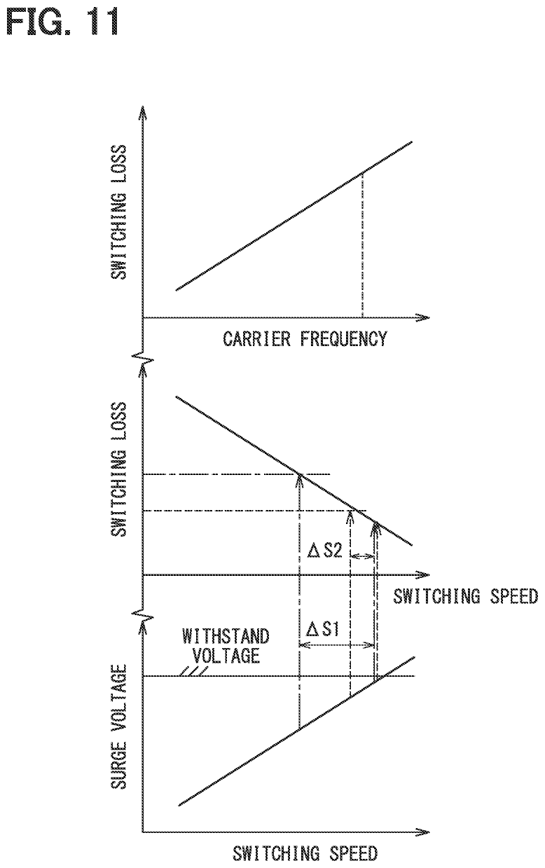

FIG. 11 is a diagram showing a relationship between a carrier frequency, a switching speed, a surge voltage, and a switching loss for generating a PWM signal.

By increasing the carrier frequency, it is possible to reduce the size and weight of passive components such as capacitors and reactors, and thereby reducing the size and weight of the power conversion device. Also, the ripple current of the motor generator can be reduced. However, increasing the carrier frequency increases the number of switching times. Therefore, as shown in FIG. 11, the switching loss increases in proportion to the carrier frequency.

By increasing the switching speed, switching losses can be reduced. However, the surge voltage increases with an increase of the switching speed. Therefore, the switching element must be operated at a speed at which the surge voltage does not exceed a withstand voltage of the switching element.

In a comparative configuration that does not include the gate resistor 46 whose resistance value is adjustable, a variation ΔS1 in the switching speed is large as shown in FIG. 11, the switching speed should be set so that the withstand voltage will not be exceeded even when the variation ΔS1 becomes large. Therefore, switching loss is large. A one-dot chain line arrow indicates the variation ΔS1, in FIG. 11.

In the present embodiment, the semiconductor element 40 of the semiconductor device 20 is provided with the gate resistor 46 whose resistance value is adjustable on the upper surface 41a of the semiconductor substrate 41. Therefore, the gate resistor 46 can be individually adjusted according to the element characteristics. As a result, a variation ΔS2 of the switching speed can be made smaller than the variation ΔS1 of the comparative example. As a result, switching loss can be reduced. A broken line arrow indicates the variation ΔS2.

As described above, the semiconductor element 40 of the present embodiment incorporates the gate resistor 46 whose resistance value is adjustable. Therefore, switching loss can be reduced with a simple configuration without the need to add components or driver functions. With a simple configuration, for example, it is possible to reduce switching loss while reducing manufacturing costs.

In addition, when adjustment of the variation in characteristics of the switching elements is performed on the driver side, it necessitates element information transmitted to the driver side, product management, and the like. In the present embodiment, since the semiconductor element 40 has therein the gate resistor 46, the resistance value can be subsequently adjusted during the inspection of the element characteristics. Therefore, management and manufacturing processes can also be simplified.

Further, in each of the semiconductor elements 40, the gate resistor 46 is adjusted after the element characteristics are inspected to adjust variations in the element characteristics. Therefore, it is possible to reduce the number of device prototype levels and the evaluation process thereof, thereby shortening the development period and reducing the development cost.

The material and structure of the gate resistor 46 are not particularly limited. In the present embodiment, the gate resistor 46 is made of silicon. The gate resistor 46 has a ladder structure, and includes the plurality of connecting parts 462 provided in parallel between the gate electrode 111 and the gate pad 441, and the adjuster pad 463 provided in each of the connecting parts 462 for adjusting the resistance value. According to the above, the connecting part 462 can be cut by applying a needle to the adjuster pad 463 and energizing it. By cutting the connecting part 462 as required, it is possible to adjust the resistance to a desired resistance value according to the element characteristics.

Specifically, each of the connecting parts 462 has the reduced-width portion 4621, the widened portion 4622 connected to one end of the reduced-width portion 4621, and the widened portion 4623 connected to the other end of the reduced-width portion 4621. The widened portions 4622 and 4623 are wider than the reduced-width portion 4621 in the width dimension. The adjuster pads 463 are provided on the widened portions 4622 and 4623, respectively. In such a configuration, by applying a voltage or an electric current between the two adjuster pads 463 provided on the common connecting part 462, the reduced-width portion 4621 having a narrow width can be cut. In other words, it is possible to selectively energize any connecting part 462.

In the present embodiment, an example in which the semiconductor element 40 has the OFF-holding pad 442 as the pad 44 is shown. However, the present disclosure is not limited to such configuration. A configuration in which the OFF-holding pad 442 is eliminated may be employed. The gate resistor 46 is connected to a gate wiring (not shown).

In the present embodiment, an example in which the gate resistor 46 has eight connecting parts 462 is described. However, the present disclosure is not limited to such configuration. The number of connecting parts 462 may be any number, as long as the number is plural.

### Second Embodiment

The second embodiment is a modification of a preceding embodiment as a basic configuration and may incorporate description of the preceding embodiment. In the above-described first embodiment, the adjuster pad is provided on the widened portion. Alternatively, the adjuster pad may be provided on the reduced-width portion.

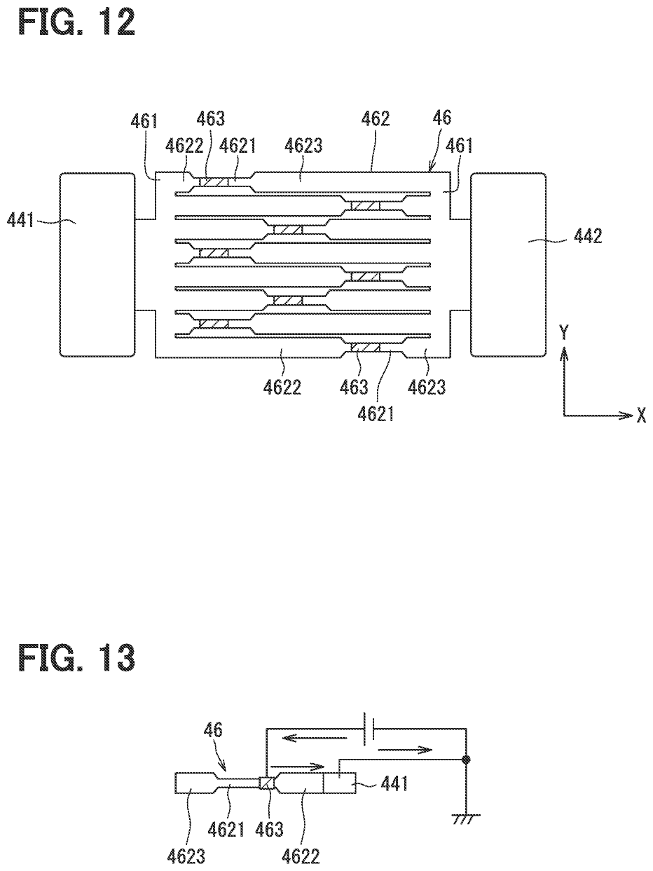

FIG. 12 is a diagram showing a pattern of the gate resistors and the arrangement of the adjuster pads in the semiconductor device according to the present embodiment. FIG. 12 corresponds to FIG. 8. FIG. 13 is a diagram showing a method of adjusting the gate resistance. FIG. 13 corresponds to FIG. 10.

The basic configuration of a semiconductor device 20 of the present embodiment is the same as the configuration shown in the preceding embodiment. The semiconductor element 40 has the gate resistor 46 made of silicon, as in the above first embodiment. The gate resistor 46 has a ladder structure with two pillars 461 and eight connecting parts 462, as in the preceding embodiment.

Each of the connecting parts 462 has a reduced-width portion 4621 and widened portions 4622 and 4623. The adjuster pad 463 is provided on the reduced-width portion 4621. One adjuster pad 463 is provided for one connecting part 462.

In a resistance adjustment process, a voltage or an electric current is applied to a position between (a) one of the gate pad 441 and the OFF-holding pad 442 and (b) the adjuster pad 463. In an example shown in FIG. 13, the voltage or the electric current is applied to a position between the gate pad 441 and the adjuster pad 463. By applying a needle to the adjuster pad 463 of the connecting part 462 to be cut, the reduced-width portion 4621 can be cut (i.e., fused).

In the present embodiment, as shown in FIG. 12, the length of the widened portion 4622 on a gate pad 441 side against which the needle is applied is made shorter than in the configuration shown in FIG. 8. Further, the adjuster pad 463 is provided at a position on the reduced-width portion 4621 near the gate pad 441. In such manner, the current density of the reduced-width portion 4621 provided with the adjuster pad 463 against which the needle is applied is heightened, thereby facilitating the cutting.

In the present embodiment, the semiconductor element 40 has the gate resistor 46 whose resistance value is adjustable on the upper surface 41a of the semiconductor substrate 41. The gate resistor 46 is made of silicon and has a ladder structure. Therefore, advantages similar to that of the configuration described in the preceding embodiment is achievable.

In the present embodiment, the adjuster pad 463 is provided on the reduced-width portion 4621. In such a configuration, by applying a voltage or an electric current to a position between (a) the gate pad 441 or the OFF-holding pad 442 and (b) the adjuster pad 463, the reduced-width portion 4621, in which the width of the current path is narrow, can be cut.

In the present embodiment, an example in which the semiconductor element 40 has the OFF-holding pad 442 as the pad 44 is shown. However, the present disclosure is not limited to such configuration. A configuration in which the OFF-holding pad 442 is eliminated may also be used. In such case, a voltage or an electric current may be applied to a position between the gate pad 441 and any adjuster pad 463.

Although an example having the widened portions 4622 and 4623 has been shown, it is not limited to such configuration. Only one of the widened portions 4622 and 4623 may be provided. For example, the widened portion 4622 may be eliminated, and the reduced-width portion 4621 may extend from the pillar portion 461 on the side of the gate pad 441.

### Third Embodiment

The third embodiment is a modification of a preceding embodiment as a basic configuration and may incorporate description of the preceding embodiment. In the preceding embodiment, the gate resistor is made of silicon. Alternatively, a gate resistor made of metal may be used.

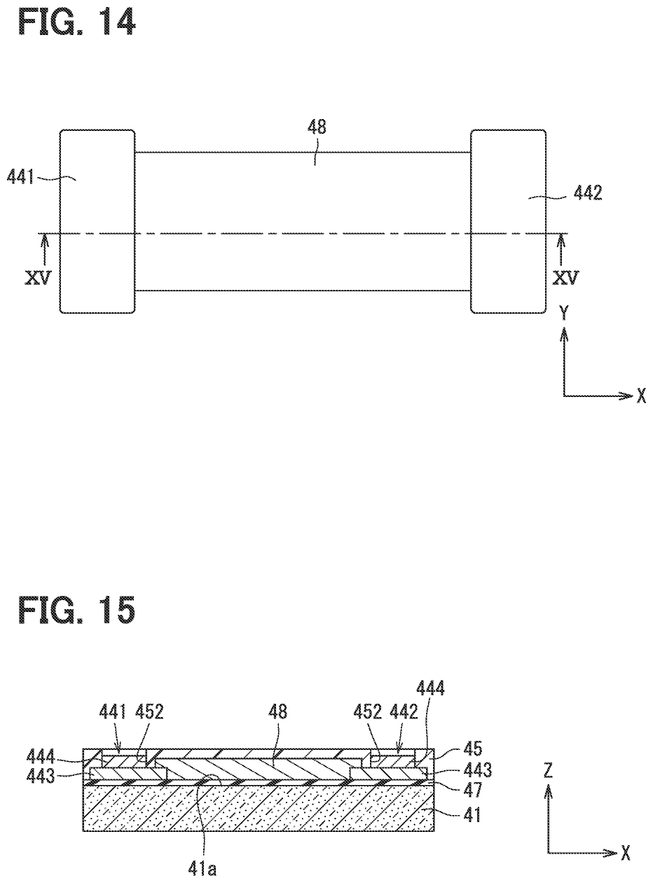

FIG. 14 is a diagram showing a pattern of a gate resistor in the semiconductor device 20 according to the third embodiment. FIG. 14 corresponds to FIG. 8. FIG. 15 is a cross-sectional view taken along a line XV-XV in FIG. 14, and FIG. corresponds to FIG. 7.

The basic configuration of a semiconductor device 20 of the present embodiment is the same as the configuration shown in the preceding embodiment. The semiconductor element 40 has a gate resistor 48 made of metal. The gate resistor 48 is a metal resistor. Any metal material can be used as long as the resistance value can be adjusted by laser trimming. As an example, a CrSi, Al alloy, or the like can be used. The gate resistor 48 has, for example, a planar and substantially-rectangular shape.

As shown in FIG. 15, the gate resistor 48 extends over the peripheral edge of the base layer 443 of the gate pad 441, the insulating film 47, and the peripheral edge of the base layer 443 of the OFF-holding pad 442. The gate resistor 48 is arranged on the peripheral portion of the base layer 443 and on the insulating film 47. One end of the gate resistor 48 is connected to the gate pad 441 and the other end of the gate resistor 48 is connected to the OFF-holding pad 442. The gate resistor 48 is covered, for example, with the protective film 45 over its entire length.

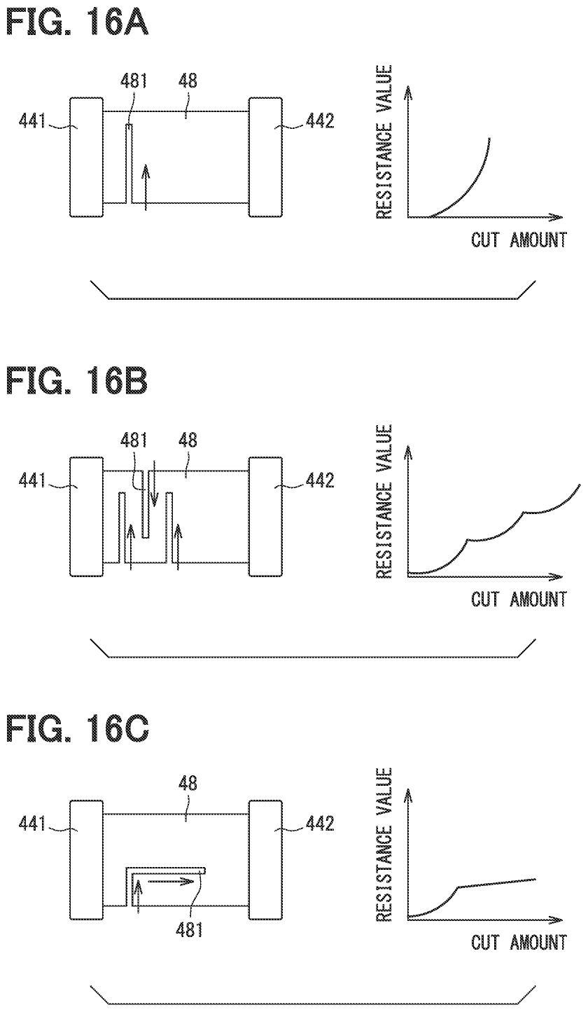

The resistance value of the gate resistor 48 can be adjusted by partially cutting it with a laser. In other words, the resistance value can be adjusted by laser trimming. FIG. 16A to 16C show some of the examples of laser cutting. FIGS. 16A to 16C also show a relationship between a cut amount and the resistance value. A solid arrow in FIGS. 16A to 16C indicates a scanning direction of the laser. In either case, the resistance value increases as the cut amount increases.

As shown in FIG. 16A, one laser-cut portion 481 extending in the width direction may be provided for the gate resistor 48. A plurality of laser-cut portions 481 extending in the width direction may be provided as shown in FIG. 16B. In such case, the laser-cut portions 481 are provided to make a meandering shape in the gate resistor 48. One of the adjacent laser-cut portions 481 has one side of the gate resistor 48 in the width direction as a starting point of cutting, and the other one of the laser-cut portions 481 has the other side of the gate resistor 48 in the width direction as the starting point of cutting. Two adjacent laser-cut portions 481 have different starting points of cutting in the width direction. The laser-cut portion 481 may have a portion extending along the width direction of the gate resistor 48 and a portion extending along the extending direction of the gate resistor 48. For example, as shown in FIG. 16C, the laser-cut portion 481 may have a substantially L-shaped plane.

In the present embodiment, the semiconductor element 40 has the gate resistor 48 in which the resistance value is adjustable on the upper surface 41a of the semiconductor substrate 41. Therefore, an effect equivalent to that of the configuration described in the preceding embodiment is achievable.

In the present embodiment, the gate resistor 48 is made of metal. By partially cutting the gate resistor 48 with a laser, it is possible to adjust it to a desired resistance value according to the element characteristics.

### Modification

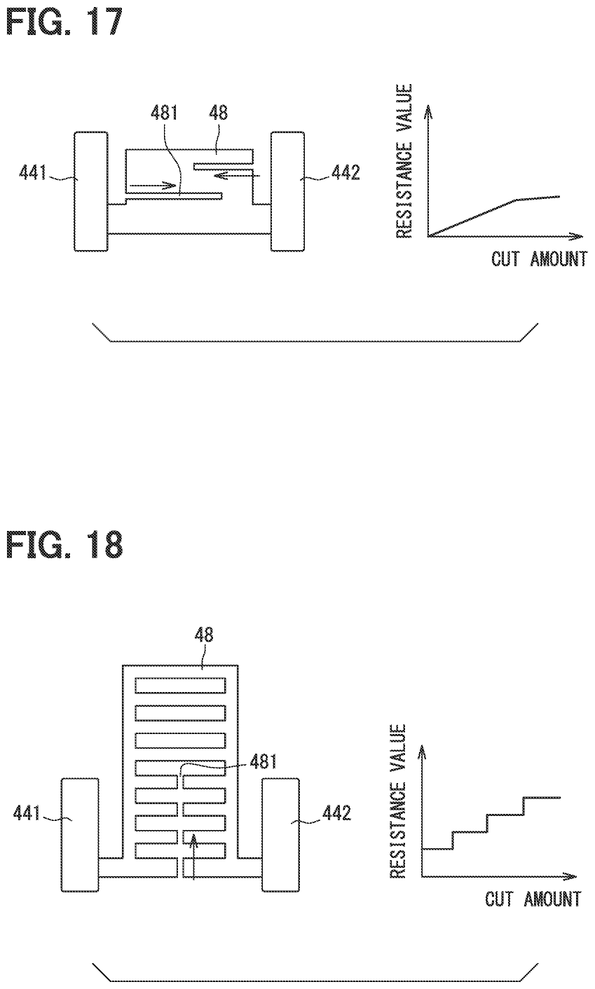

The planar shape of the gate resistor 48 is not limited to a rectangular shape. For example, as shown in FIG. 17, a hat shape may be adopted. In FIG. 17, the laser-cut portion 481 is provided in a hat-shaped convex portion. The laser-cut portion 481 extends along the extending direction of the gate resistor 48.

As shown in FIG. 18, a ladder shape may be employed. In FIG. 18, the laser-cut portions 481 are provided at a plurality of connecting parts. The resistance value can be raised by increasing the number of connecting parts having the laser-cut portion 481.

Although an example in which the gate resistor 48 is covered with the protective film 45 has been shown, it is not limited to such configuration. At least a part of the gate resistor 48 may be exposed from the protective film 45.

### Other Embodiments

The disclosure in the present disclosure and drawings is not limited to the exemplified embodiments. The present disclosure includes embodiments described above and modifications of the above-described embodiments made by a person skilled in the art. For example, the present disclosure is not limited to a combination of the components and/or elements described in the embodiments. The disclosure may be implemented in various combinations. The present disclosure may include additional configuration that can be added to the above-described embodiments. The present disclosure also includes modifications from which components/elements of the above-described embodiments are omitted at least partially. The present disclosure includes replacements (i.e., swap) of components and/or elements between one embodiment and another embodiment, or combinations of components and/or elements between one embodiment and another embodiment The technical scope disclosed in the present disclosure is not limited to the above-described embodiments. It should be understood that some disclosed technical ranges are indicated by description of claims, and includes every modification within the equivalent meaning and the scope of description of claims.

The disclosure in the specification, the drawings and the like are not limited by the description of the claims. The disclosures in the specification, the drawings, and the like include the technical ideas described in the claims, and further extend to a wider variety of technical ideas than those described in the claims. Therefore, various technical ideas can be extracted from the disclosure of the specification, the drawings and the like without being limited to the description of the claims.

When an element or a layer is described as “disposed above” or “connected”, the element or the layer may be directly disposed above or connected to another element or another layer, or an intervening element or an intervening layer may be present therebetween. In contrast, when an element or a layer is described as “disposed directly above” or “directly connected”, an intervening element or an intervening layer is not present. Other terms used to describe the relationships between elements (for example, “between” vs. “directly between”, and “adjacent” vs. “directly adjacent”) should be interpreted similarly. As used herein, the term “and/or” includes any combination and all combinations relating to one or more of the related listed items. For example, the term A and/or B includes only A, only B, or both A and B.

Spatial relative terms “inside”, “outside”, “back”, “bottom”, “low”, “top”, “high”, etc. are used herein to facilitate the description that describes relationships between one element or feature and another element or feature. Spatial relative terms can be intended to include different orientations of a device in use or operation, in addition to the orientations depicted in the drawings. For example, when a device in the drawing is flipped over, an element described as “below” or “directly below” another element or feature is then positioned “above” the other element or feature. Therefore, the term “below” can include both above and below. The device may be oriented in the other direction (i.e., rotated 90 degrees or in any other direction) and the spatially relative terms used herein are interpreted accordingly.

The vehicle drive system 1 is not limited to the above-described configuration described in the foregoing embodiments. For example, although an example provided with one motor generator 3 has been shown, it is not limited to such configuration. A plurality of motor generators may be provided in the vehicle drive system 1. Although an example in which the power conversion device 4 includes the inverter 6 as a power conversion unit has been shown, the present disclosure is not limited to such configuration. For example, the configuration may include a plurality of inverters. At least one inverter and a converter may be included in the configuration. The configuration may include a converter only.

A switching element is not limited to the IGBT 11. For example, a MOSFET may be employed. MOSFET is an abbreviation of Metal Oxide Semiconductor Field Effect Transistor. In case of using an n-channel MOSFET, the source electrode corresponds to a main electrode on the upper surface, that is, corresponds to a first main electrode, and the drain electrode corresponds to a second main electrode. In case of using a MOSFET, a parasitic diode (i.e., a body diode) may be used as a reflux diode, or an external diode may be used as a reflux diode.

For example, in at least one of the above embodiments of the present disclosure, the semiconductor device 20 includes the sealing body 30, the semiconductor element 40, the wiring members 50 and 60, the conductive spacer 70, the external connection terminal 80, and the like. However, the present disclosure is not limited to such configuration. The semiconductor device 20 may include the semiconductor element 40, at least.

In at least one of the above embodiments of the present disclosure, the reverse surfaces 50b and 60b of the wiring members 50 and 60 are exposed from the sealing body 30. However, the present disclosure is not limited to such configuration. One of the reverse surfaces 50b and 60b may be covered with the sealing body 30, at least. One of the reverse surfaces 50b and 60b may be covered with an insulating member (not shown) that is different from the sealing body 30, at least. Although an example in which the semiconductor device 20 includes the sealing body 30 is shown, the present disclosure is not limited to such configuration. A configuration without the sealing body 30 may also be employed.

In at least one of the above embodiments of the present disclosure, the semiconductor device 20 includes only one semiconductor element 40 that forms one arm, the present disclosure is not limited to such configuration. The semiconductor device 20 may include a plurality of semiconductor elements 40 forming one arm. That is, a plurality of semiconductor elements 40 may be connected in parallel to form one arm. In such case, the conductive spacer 70 is provided individually for each of the semiconductor elements 40. Further, the semiconductor device 20 may include a plurality of semiconductor elements 40 forming the upper and lower arm circuits 9 for one phase. A plurality of semiconductor elements 40 forming the upper and lower arm circuits 9 of multiple phases may be provided.

Instead of the conductive spacer 70, the wiring member 50 may have a convex portion.

An example of a double-sided heat dissipation structure has been shown as the semiconductor device 20. However, the present disclosure is not limited thereto. The semiconductor device 20 can also have a single-sided heat dissipation structure. For example, the collector electrode 43 may be connected to a heat sink or a metal body on a substrate, and the emitter electrode 42 may be connected to a lead.

An external gate resistor may be combined with the gate resistor that is built in the semiconductor element 40. That is, the resistance value may be adjusted by the built-in gate resistors 46 and 48 and by the external gate resistor. The external gate resistor may be connected in series with the gate resistors 46 and 48, for example.

What is claimed is:

1. A semiconductor device comprising:
a semiconductor substrate in which an element having a gate electrode is provided;
a first main electrode arranged on a first surface of the semiconductor substrate;
a second main electrode arranged on a second surface opposite to the first surface in a substrate thickness direction;
a gate pad arranged on the first surface of the semiconductor substrate at a position different from a position of the first main electrode; and
a gate resistor having an adjustable resistance value,
wherein the gate resistor is arranged on the first surface of the semiconductor substrate, and is connected to a position between the gate electrode and the gate pad.

2. The semiconductor device according to claim 1, wherein
the gate resistor is made of silicon, and is configured to have a ladder structure, and
the gate resistor includes:
a plurality of connecting parts provided in parallel between the gate electrode and the gate pad; and
a plurality of adjuster pads provided respectively in the plurality of connecting parts to adjust the resistance value.

3. The semiconductor device according to claim 2, wherein
each of the connecting parts includes:
a reduced-width portion;
a first widened portion that is connected to one end of the reduced-width portion and is wider than the reduced-width portion; and
a second widened portion that is connected to an another end of the first widened portion and is wider than the reduced-width portion, and
the adjuster pad is provided in the first widened portion and the second widened portion in each of the connecting parts.

4. The semiconductor device according to claim 2, wherein
each of the connecting parts includes:
a reduced-width portion; and
a widened portion that is connected to one end of the reduced-width portion and is wider than the reduced-width portion, and
the adjuster pad is provided in the reduced-width portion in each of the connecting parts.

5. The semiconductor device according to claim 1, wherein
the gate resistor is made of metal.
